(19) United States
(12) Patent Application Publication
(10) Pub. No.: US 2026/0301156 A1
(43) Pub. Date: Oct. 1, 2026

(54) METHOD FOR MEASURING OVERLAY USING SCANNING ELECTRON MICROSCOPE DEVICE

(71) Applicant: SAMSUNG ELECTRONICS CO., LTD., Suwon-si (KR)

(72) Inventors: Yeny Yim, Suwon-si (KR); Jhongkwon Kim, Suwon-si (KR); Wonhee Lee, Suwon-si (KR); Chulmoo Kang, Suwon-si (KR); Hyeju Kang, Suwon-si (KR); Woongkyu Son, Suwon-si (KR); Sungeun Eom, Suwon-si (KR); Taehyun Yun, Suwon-si (KR); Sanghyun Joo, Suwon-si (KR)

(73) Assignee: SAMSUNG ELECTRONICS CO., LTD., Suwon-si (KR)

(21) Appl. No.: 19/353,945

(22) Filed: Oct. 9, 2025

(30) Foreign Application Priority Data
Mar. 28, 2025 (KR) 10-2025-0040433

(51) Int. Cl. G06T 7/00; G06T 7/60; G06T 7/73; H01J 37/22

(52) U.S. Cl. CPC G06T 7/001; G06T 7/60; G06T 7/74; H01J 37/222; G06T 2207/10061; G06T 2207/20081; G06T 2207/30148; H01J 2237/221

(57) ABSTRACT

A method of measuring an overlay includes obtaining a plurality of first images, each of the plurality of first images being generated by integrating N first frames generated by a scanning electron microscope (SEM) device, generating a plurality of training images by respectively applying noise to the plurality of first images, inputting the plurality of training images into a machine learning model, obtaining, from the machine learning model, predicted noise by determining, by the machine learning model, noise in each of the plurality of training images, training the machine learning model by respectively comparing the predicted noise of the plurality of training images with the noise applied to the plurality of first images, obtaining an original image in which M second frames generated by the SEM device are integrated, obtaining a result image by inputting the original image into the machine learning model for which training is completed.

### CROSS-REFERENCE TO RELATED APPLICATION(S)

This application is based on and claims priority to Korean Patent Application No. 10-2025-0040433, filed on Mar. 28, 2025, in the Korean Intellectual Property Office, the disclosure of which is incorporated herein by reference in its entirety.

### BACKGROUND

The present disclosure relates to a method for measuring an overlay using a scanning electron microscope device.

A semiconductor process may include a photo process, an etching process, a deposition process, and the like, for forming a plurality of layers on a substrate such as a wafer or the like, and a plurality of patterns may be formed on each of the plurality of layers. In order to increase yield of the semiconductor process, an overlay indicating an alignment state of patterns formed on different layers may be determined.

Recently, in order to accurately determine an overlay, a method for measuring the overlay in a semiconductor chip using an image captured by a scanning electron microscope (SEM) device has been proposed. However, in such a method, in order to increase accuracy of measurement and determination of the overlay, the scanning electron microscope device needs to capture images with high quality, and in the process, a problem may occur in which a period of time for the measurement may be relatively long.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a method for measuring an overlay that may be capable of shortening a period of time required for determining an overlay by improving low-quality images generated by a scanning electron microscope device using a machine learning model.

Additional aspects will be set forth in part in the description which follows and, in part, will be apparent from the description, or may be learned by practice of the presented embodiments.

According to an aspect of an example embodiment, a method of measuring an overlay may include obtaining a plurality of first images, each of the plurality of first images being generated by integrating N first frames generated by a scanning electron microscope (SEM) device, where N is a natural number equal to or greater than 2, generating a plurality of training images by respectively applying noise to the plurality of first images, inputting the plurality of training images into a machine learning model, obtaining, from the machine learning model, predicted noise by determining, by the machine learning model, noise in each of the plurality of training images, training the machine learning model by respectively comparing the predicted noise of the plurality of training images with the noise applied to the plurality of first images, obtaining an original image in which M second frames generated by the SEM device are integrated, where M is a natural number less than N, obtaining a result image by inputting the original image into the machine learning model for which training is completed and measuring an overlay based on the result image.

According to an aspect of an example embodiment, a method for measuring an overlay may include inputting a training image into a machine learning model, the training image including an image captured by a SEM device to which noise is applied, determining a loss function based on a predicted average value and a predicted standard deviation value that are output by the machine learning model, and an actual average value and an actual standard deviation value in the noise applied to the training image, training the machine learning model, and based on the training being completed, storing the machine learning model in a server, the machine learning model being configured to control the SEM device.

According to an aspect of an example embodiment, a method of measuring an overlay may include obtaining an original image in which M frames generated by a SEM device are integrated, where M is a natural number equal to or greater than 2, obtaining a predicted average value and a predicted standard deviation value that estimate noise in the original image by inputting the original image into a machine learning model, generating a result image by processing the original image using the predicted average value and the predicted standard deviation value, determining a center position of each of structures in the original image based on the result image, and measuring an overlay based on the center position of each of the structures.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a scanning electron microscope device applied to a method for measuring an overlay according to an embodiment;

FIG. 2 is a diagram illustrating a system for performing a method for measuring an overlay according to an embodiment;

FIG. 3 is a diagram illustrating a wafer input into a method for measuring an overlay according to an embodiment;

FIGS. 4A and 4B are diagrams illustrating a method for measuring an overlay according to an embodiment′

FIG. 5 is a flowchart illustrating a method for measuring an overlay according to an embodiment;

FIGS. 6 and 7 are diagrams illustrating a method for measuring an overlay according to an embodiment;

FIG. 8 is a flowchart illustrating a method for measuring an overlay according to an embodiment;

FIGS. 9 and 10 are diagrams illustrating a method for measuring an overlay according to an embodiment;

FIG. 11 is a flowchart illustrating a method for measuring an overlay according to an embodiment;

FIG. 12 is a diagram illustrating a method for manufacturing a semiconductor device according to an embodiment;

FIG. 13 is a flowchart illustrating a method for measuring an overlay according to an embodiment;

FIGS. 14, 15, 16 and 17 are diagrams illustrating a method for measuring an overlay according to an embodiment;

FIG. 18 is a flowchart illustrating a method for measuring an overlay according to an embodiment;

FIG. 19 is a flowchart illustrating a method for measuring an overlay according to an embodiment; and

FIG. 20 is a block diagram of a system according to one or more embodiments

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

In addition, terms such as “unit” and “module” described in the specification may indicate a unit that processes at least one function or operation, and this may be implemented as hardware or software, or may be implemented as a combination of hardware and software.

The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

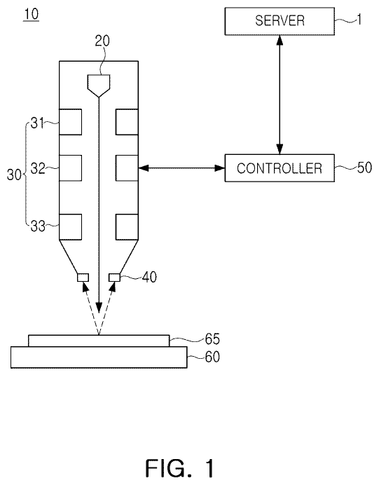

FIG. 1 is a diagram illustrating a scanning electron microscope device applied to a method for measuring an overlay according to an embodiment.

Referring to FIG. 1, a scanning electron microscope (SEM) device 10 according to an embodiment may include an electron beam source 20, a lens assembly 30, an electron detector 40, a controller 50, and the like. The SEM device 10 may emit an electron beam to an object 65 disposed on a stage 60, and may collect a signal emitted from the object 65 by the electron detector 40. The controller 50 may generate an image of the object 65 using a signal collected by the electron detector 40. The object 65 may be a substrate on which a semiconductor process is performed, and may be a wafer in an embodiment. For example, the signal emitted from the object 65 by the electron beam irradiated to the object 65 may include secondary electrons (SE), back scattered electrons (BSE), X-rays, visible light, cathode fluorescence, or the like.

The electron beam source 20 may generate and emit an electron beam, and the electron beam emitted from the electron beam source 20 may be accelerated and focused by the lens assembly 30 and emitted to the object 65. For example, the electron beam source 20 may include an electron gun, and the electron gun may generate an electron beam by heating a filament formed of tungsten or the like to generate electrons and accelerating the electrons by applying a voltage.

The lens assembly 30 may include a first focusing lens 31, a second focusing lens 32, an objective lens 33, and the like. The first and second focusing lenses 31 and 32 may focus electron beams such that the electron beams emitted from the electron beam source 20 are effectively gathered at one point of the object 65. For example, as a diameter of an electron beam emitted to the object 65 decreases, resolution of an image acquired by the controller 50 may be improved, and the lens assembly 30 may include two or more focusing lenses (31 and 32) to increase the resolution of the image. A diameter of an electron beam emitted from the electron beam source 20 may gradually decrease while passing through the first and second focusing lenses 31 and 32.

The objective lens 33 may focus the electron beam focused by the first and second focusing lenses 31 and 32 on the object 65. For example, the objective lens 33 may determine a size of the electron beam emitted to the object 65. A distance between the objective lens 33 and the object 65 may be defined as a working distance, and the diameter of the electron beam irradiated on the object 65 may be changed depending on the working distance. Therefore, a position of the objective lens 33 may be adjusted to adjust resolution of an image corresponding to the object 65.

The controller 50 may generate an image of a target region in which an electron beam is incident on the object 65 and a signal is emitted in response thereto using a signal collected by the electron detector 40. The image generated by the controller 50 may be transmitted to a server 1, and the server 1 may measure an overlay for the object 65 based on the image. As quality of the image generated by the controller 50, the overlay may be accurately measured, but a period of time required for measuring an overlay may be longer.

In an embodiment, the SEM device 10 may be operated in a manner in which a low-quality original image is generated to minimize an increase in a period of time required for overlay measurement. The controller 50 may generate an original image with low quality, for example, low frames-per-second (FPS), and may transmit the same to the server 1.

The server 1 may improve quality of the low-quality original image to generate a result image, and may use the result image to determine an overlay. In an embodiment, the server 1 may include a machine learning model trained to predict noise included in the low-quality original image. The server 1 may acquire a result image with improved quality by predicting the noise included in the original image received from the controller 50 using the machine learning model, and processing the original image based on the predicted noise. For example, the result image may have a quality similar to an image in which a relatively larger number of frames are integrated, as compared to the original image. Therefore, the period of time required for overlay measurement may be shortened, as compared to a method of generating an original image with high quality, and accuracy of overlay measurement may increase to improve yield of a semiconductor process performed on the object 65.

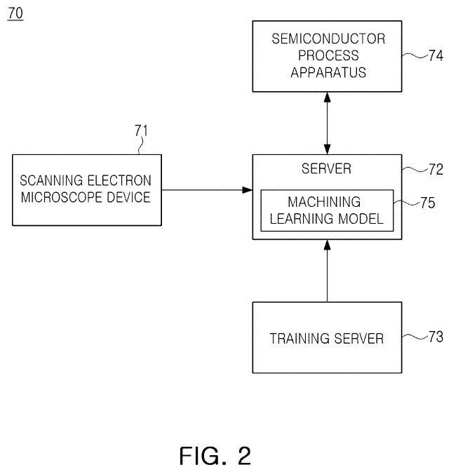

FIG. 2 is a diagram illustrating a system for performing a method for measuring an overlay according to an embodiment.

Referring to FIG. 2, a semiconductor process system 70 according to an embodiment may include a SEM device 71, a server 72, a training server 73, a semiconductor process apparatus 74, and the like. The SEM device 71 may operate according to an embodiment described above with reference to FIG. 1, and may generate an original image required to measure an overlay of an object undergoing a semiconductor process in the semiconductor process apparatus 74, for example.

The original image generated by the SEM device 71 may be transmitted to the server 72, and the server 72 may process the original image to measure the overlay. For example, to improve throughput of the semiconductor process being performed in the semiconductor process system 70, the SEM device 71 may capture an image of the object for a short period of time to generate the original image. In this case, quality of the original image may be low.

In an embodiment, the SEM device 71 may integrate frames acquired by capturing the image of the object multiple times to generate a single original image. Quality of an original image may be determined according to the number of integrated frames. As the number of integrated frames increases, quality of the original image may increase, but a period of time required for generating a single original image may increase, and productivity may be reduced.

In an embodiment, the server 72 may process an original image in which a small number of frames are integrated to generate a result image with improved quality, and measure an overlay using the result image. For example, the server 72 may improve quality of the original image using a machine learning model 75 to generate a result image, and the result image may have a similar quality to an image generated by integrating more frames than frames integrated for generating the original image.

The machine learning model 75 may be trained by the training server 73 and then stored in the server 72. In the embodiment illustrated in FIG. 2, the server 72 performing inference using the machine learning model 75 and the training server 73 training the machine learning model 75 are illustrated to be implemented separately, but embodiments are not limited thereto. For example, training of the machine learning model 75 may be executed in the server 72. Also, according to the embodiment, the SEM device 71 and the server 72 may be implemented as a single device.

The server 72 may measure the overlay using the result image of which quality has been improved by the machine learning model 75, and may transmit a measurement result of the overlay to the semiconductor process apparatus 74. The semiconductor process apparatus 74 may adjust process variables or the like with reference to the measurement result of the overlay, and thus yield of the semiconductor process performed in the semiconductor process apparatus 74 may be improved.

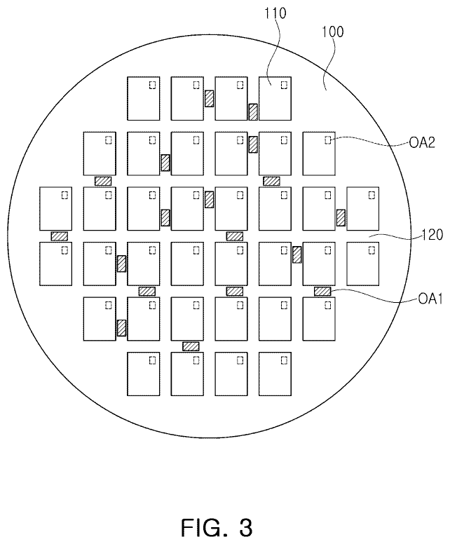

FIG. 3 is a diagram illustrating a wafer input into a method for measuring an overlay according to an embodiment.

Referring to FIG. 3, a wafer 100 according to an embodiment may include a plurality of chip regions 110 and a scribing region 120 defined between the plurality of chip regions 110. A semiconductor die may be formed in each of the plurality of chip regions 110, and when a process is completed, a dicing process may be performed in the scribing region 120 to separate a plurality of semiconductor dies from each other.

As illustrated in FIG. 3, in an embodiment, a first overlay region OA1 for measuring an overlay may be formed in the scribing region 120. An overlay key pattern may be formed in the first overlay region OA1, and the overlay key pattern may include a lower overlay key pattern and an upper overlay key pattern, stacked on each other.

In addition, as illustrated in FIG. 3, in an embodiment, a second overlay region OA2 for measuring an overlay may be formed in a chip region 110 corresponding to the semiconductor die. For example, the second overlay region OA2 may not be a region in which a separate overlay key pattern for overlay measurement is formed, and may be a region defined in a cell region involved in an operation of the semiconductor die. The second overlay region OA2 may be photographed with a SEM device to acquire an image in which patterns included in the second overlay region OA2 appear, and the acquired image may be used for overlay measurement. In an embodiment, errors of the overlay measured from the overlay key pattern may be reduced by using the image acquired in the second overlay region OA2.

In on-cell overlay measurement measuring an overlay using patterns formed in the cell region such as the second overlay region OA2, measurement time may be determined by a SEM device generating an image of the second overlay region OA2. For example, a SEM device may generate one original image by integrating two or more frames acquired by photographing a target region including the second overlay region OA2 multiple times. As the number of frames integrated to generate one original image increases, quality of an original image may be improved and an overlay may be accurately measured. As the number of frames increases, a period of time required for overlay measurement may increase.

In an embodiment, a machine learning model may be used to improve accuracy of overlay measurement and shorten a measurement period of time. The machine learning model may be trained to predict noise included in an original image generated by integrating a small number of frames. The original image may be processed, based on the noise predicted by the machine learning model, to generate a result image having a similar quality to an image generated by integrating a large number of frames. Therefore, a measurement period of time required for photographing the second overlay region OA2 with a SEM device and measuring the overlay may be shortened, while improving accuracy of overlay measurement.

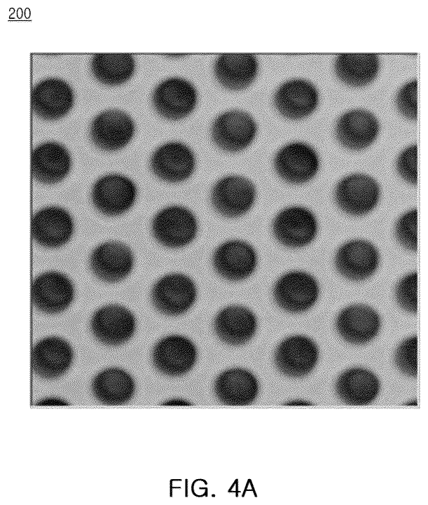

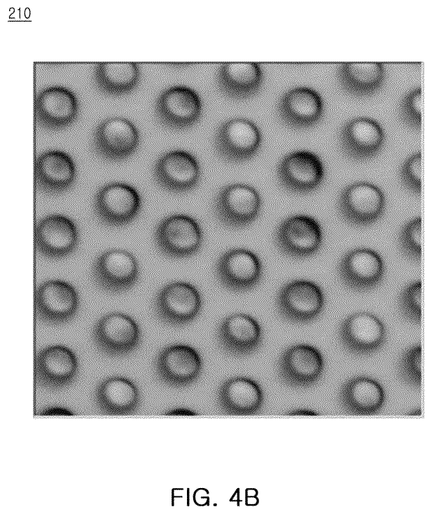

FIGS. 4A and 4B are diagrams illustrating a method for measuring an overlay according to an embodiment.

As in the embodiment described above with reference to FIG. 3, an overlay key pattern may be formed in a scribing region of a wafer. An overlay of structures formed by a semiconductor process performed on the wafer may be measured using the overlay key pattern formed in the scribing region of the wafer.

Due to a difference in positions between the scribing region and chip regions, an error may occur between an overlay measured using the overlay key pattern formed in the scribing region and an overlay of structures formed in the chip regions of the wafer. Therefore, even though the overlay key patterns are accurately aligned, misalignment may occur in the structures in the chip region. Conversely, when misalignment occurs in overlay key patterns, misalignment may not occur in the structures in the chip region.

To solve the problems, one or more example embodiments may perform a miss reading correction (MRC) operation compensating for the error of the overlay measured with the overlay key patterns using an image captured using a SEM device to capture at least a portion of the chip region, and the overlay may be accurately measured. FIGS. 4A and 4B may be images (200 and 210) acquired by capturing a portion of a chip region included in the wafer or the like using a SEM device.

In an embodiment illustrated in FIGS. 4A and 4B, the SEM device may capture a region including a plurality of holes to capture a first image 200 and a second image 210. For example, the first image 200 and the second image 210 may be images acquired by capturing different heights in the same region, and the overlay may be measured by comparing positions of patterns displayed in the first image 200 with positions of patterns displayed in the second image 210. As described above, the first image 200 and the second image 210 acquired by photographing the chip region may be used for the MRC operation to compensate for accuracy of overlay measurement.

Quality of each of the first image 200 and the second image 210 acquired by photographing the chip region with the SEM device may be determined according to the number of frames integrated to generate each of the first image 200 and the second image 210. For example, when a large number of frames are acquired by increasing the number of shots and the acquired frames are integrated to generate one image, quality of the image may be improved.

To acquire the large number of frames by increasing the number of shots, the measurement time of the overlay may inevitably increase. In an embodiment, one original image may be configured with only a small number of frames acquired with a small number of shots and quality of the original image may be improved using a machine learning model, to shorten a measurement period of time and improve accuracy of the overlay measurement at the same time. The machine learning model may be a model trained to predict noise included in the original image, and may be implemented as a generative model, for example.

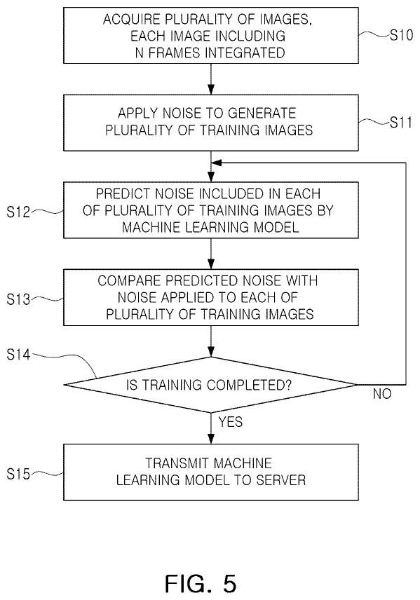

FIG. 5 is a flowchart illustrating a method for measuring an overlay according to an embodiment.

FIG. 5 is a flowchart illustrating a training method of a machine learning model for executing a method for measuring an overlay according to an embodiment. As described above, the machine learning model for executing a method for measuring an overlay according to an embodiment may be a generative model.

Referring to FIG. 5, a method for measuring an overlay according to an embodiment may start with acquiring a plurality of images, each image including N frames integrated in operation S10. Each of the N frames may be an image generated by a SEM device emitting an electron beam to a target region of an object and using an electron beam reflected from the target region, and N may be a natural number equal to or greater than 2.

The SEM device may generate N frames (N may be a natural number equal to or greater than 2) by scanning the electron beam multiple times through the same field-of-view (FOV). A server controlling the SEM device may generate the plurality of images in which N frames are integrated, and for example, as the number of frames integrated to generate one image, which may be N, increases, quality of the image may be improved. For example, as N increases, noise of the image may decrease, and shapes of patterns included in the image may be clearly expressed. The image generated by the SEM device in S10 may be generated with high quality, and for example, the SEM device may generate one image in which 16 or more frames are integrated.

In an embodiment, the plurality of images acquired by the SEM device may be transmitted to a server in which training of a machine learning model is performed. As described above with reference to FIG. 2, training of the machine learning model may be executed on a training server. The training server may apply noise to each of the plurality of images to generate a plurality of training images in operation S11.

The noise applied to each of the plurality of images in operation S11 may be Gaussian noise. In an embodiment, the training server may apply noise of different intensities to one image, to generate two or more training images from the one image.

When a plurality of training images are generated, the training server may input each of the plurality of training images to the machine learning model. The machine learning model may output predicted noise, predicting the noise included in each of the plurality of training images in operation S12. The training server may compare the predicted noise output by the machine learning model in operation S12 with the noise applied to each of the plurality of images in operation S13. The noise compared to the predicted noise in operation S13 may be the noise applied in operation S11 to each of the plurality of images generated by the SEM device in operation S10.

In operation S14, the training server may determine whether a training task for the machine learning model is completed with reference to a comparison result in operation S13. For example, the machine learning model may output predicted noise including a predicted mean value and a predicted standard deviation value of the noise included in the input training image. The training server may compare an actual mean value and an actual standard deviation value of the Gaussian noise applied in operation S11 to the training image input to the machine learning model with the predicted mean value and the predicted standard deviation value.

In operation S14, the training server may apply a predetermined loss function to the actual average value and the predicted average value, and the actual standard deviation value and the predicted standard deviation value, to determine whether the training for the machine learning model is completed. For example, the training server may train the machine learning model such that a value of the loss function decreases. When the training is determined to be incomplete as a result of determination in operation S14, the machine learning model may re-predict the noise included in the training image, and a task of comparing the predicted noise re-predicted by the machine learning model with the noise included in the training image may be repeatedly performed again (i.e., operations S12, S13 and S14 may be repeated until the loss function is sufficiently reduced).

When the training is determined to be complete as a result of the determination in operation S14, the training server may terminate the training of the machine learning model and transmit the machine learning model to the server in operation S15. For example, the server receiving and storing the machine learning model in operation S15 may be a server controlling a SEM device, a semiconductor process facility performing a semiconductor process, or the like. Depending on an embodiment, the training server may be implemented separately from the server or may be implemented as a single integrated server.

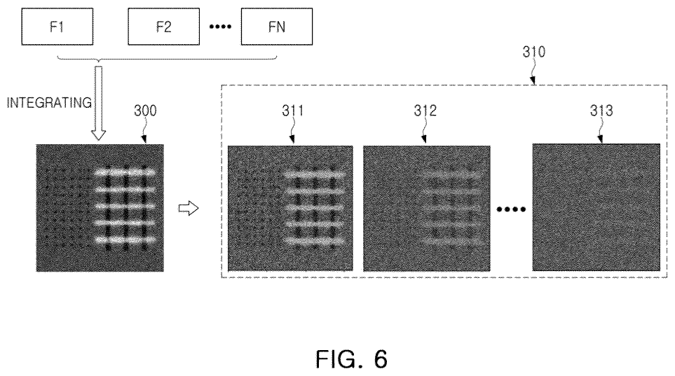

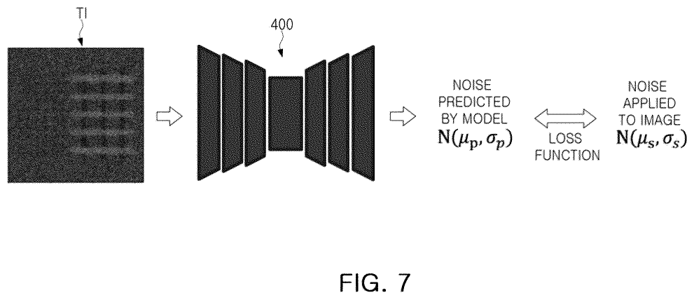

FIGS. 6 and 7 are diagrams illustrating a method for measuring an overlay according to an embodiment.

FIG. 6 is a diagram illustrating a method of generating a plurality of training images required for training a machine learning model. Referring to FIG. 6, a plurality of frames F1 to FN generated by a SEM device may be integrated (e.g., combined) to generate a single image 300.

A task of integrating the plurality of frames F1 to FN may be executed by a server, a computer device, or the like, controlling the SEM device. For example, the SEM device may emit an electron beam to a target region multiple times with the same FOV to generate the N frames. The server controlling the SEM device may integrate the N frames F1 to FN, and may determine, for example, an added average of the N frames, to acquire the single image 300. The number of N frames F1 to FN integrated to acquire the single image 300 may increase to improve quality of the image 300.

When the image 300 is generated, the server may apply noise to the image 300 to generate a plurality of training images 310. For example, the server may apply a first noise to the image 300 to generate a first training image 311, apply a second noise, different from the first noise, to the image 300 to generate a second training image 312, and apply a third noise, different from the first noise and the second noise, to the image 300 to generate a third training image 313.

The first noise, the second noise, and the third noise may be Gaussian noise, respectively. The first noise, the second noise, and the third noise may have different values in at least one of an average or a standard deviation. In an embodiment illustrated in FIG. 6, among the first to third training images 311 to 313, the relatively weakest noise may be applied to the first training image 311, and the relatively strongest noise may be applied to the third training image 313.

FIG. 7 is a diagram illustrating a training task of a machine learning model 400. Referring to FIG. 7, to train the machine learning model 400, a training image TI may be input to the machine learning model 400. The training image TI may be an image generated by a SEM device, and may be an image generated by forcibly applying Gaussian noise to the image generated by the SEM device, as described above with reference to FIG. 6.

The machine learning model 400 may be a generative model. The machine learning model 400 receiving the training image TI may predict noise (N(μp,σp)) included in the training image TI. For example, as illustrated in FIG. 7, the machine learning model 400 may output a predicted average value (μp) and a predicted standard deviation value (σp) of the noise included in the training image TI.

A training server performing the training task of the machine learning model 400 may compare the predicted average value (μp) and the predicted standard deviation value (σp), output by the machine learning model 400 that has received the training image TI, with an actual average value (μs) and an actual standard deviation value (σs) of the noise applied to the training image TI, respectively. The training server may compare the predicted average value (μp) with the actual average value (μs), and the predicted standard deviation value (σp) with the actual standard deviation value (σs), using a predetermined loss function, and may train the machine learning model 400 based on comparison results.

The training server may perform training of the machine learning model 400 using the plurality of training images 310 generated as described above with reference to FIG. 6. When the training of the machine learning model 400 is completed, the training server may transmit the trained machine learning model 400 to the server. The server receiving the machine learning model 400 may be a server controlling the SEM device, a semiconductor process facility performing a semiconductor process, or the like. The server may be implemented as a single device with the training server or may be implemented as a separate device.

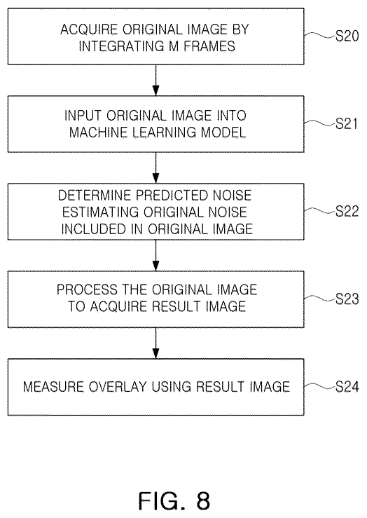

FIG. 8 is a flowchart illustrating a method for measuring an overlay according to an embodiment.

FIG. 8 is a flowchart illustrating a method for measuring an overlay performed using a machine learning model of which training is completed. As an example, a machine learning model used to execute a method for measuring an overlay according to an embodiment may be trained as in the embodiment described above with reference to FIGS. 5 to 7.

Referring to FIG. 8, a method for measuring an overlay according to an embodiment may start with acquiring an original image in which M frames are integrated in operation S20. Each of the M frames may be an image generated by a SEM device emitting an electron beam to a target region of an object and using an electron beam reflected from the target region, and M may be a natural number equal to or greater than 2. For example, M may be smaller than the number of frames N integrated in the image generated by the SEM device for training a machine learning model.

A process of integrating the M frames to acquire the original image may be as described above. For example, the SEM device may generate M frames by scanning the electron beam multiple times with the same field-of-view (FOV). A server controlling the SEM device may integrate the M frames using a weighted average or the like, to acquire the original image.

The server may input the original image generated in operation S20 into the machine learning model in operation S21. The machine learning model may determine predicted noise that estimates original noise included in the input original image in operation S22. For example, the machine learning model may output a predicted average value and a predicted standard deviation value, predicting the original noise.

The server may process the original image with reference to the predicted noise determined by the machine learning model, to acquire a result image with improved quality than the original image in operation S23. For example, the result image generated in operation S23 may have quality similar to that of an image generated by integrating more than M frames. The server may measure an overlay using the result image operation S24.

The overlay measured in operation S24 may be an on-cell overlay (OCO) measured from patterns formed in at least one of chip regions included in a wafer. The server may perform a MRC operation to reduce an error of the overlay measured using an overlay key pattern by reflecting the on-cell overlay measured in operation S24 to the overlay measured using the overlay key pattern formed in the scribing region of the wafer. Therefore, accuracy of overlay measurement may be improved, and yield of the semiconductor process may be improved.

In a method for measuring an overlay according to an embodiment, an original image input to a machine learning model may be generated by integrating M frames. For example, M may be less than the number of frames integrated in an image generated for training the machine learning model. For example, training images for training the machine learning model may be generated by forcibly applying noise to an image in which N frames generated by the SEM device are integrated. In this case, the number of frames integrated in an image generated by the SEM device to prepare the training images, N, may be greater than the number of frames integrated in an original image for overlay measurement, M.

Therefore, after training of the machine learning model is completed, a period of time required for a task of generating the original image for actual overlay measurement may be shortened, and productivity of an overlay measurement task may be improved. In addition, a larger number of original images may be acquired during the same time, and an overlay may be measured based thereon, accuracy of the overlay measurement task may be improved. In other words, the number of frames for training the machine learning model is greater than the number of frames needed for measuring the overlay by executing the trained machine learning model, which reduces the number of images that need to be obtained and increases the speed for measuring an overlay.

For example, the number of times an electron beam is emitted to a chip region for on-cell overlay measurement may correspond to the number of frames integrated to generate the original image. In an embodiment, the original image for on-cell overlay measurement may be generated by integrating a relatively small number of frames, and the number of times an electron beam is irradiated on the chip region may be reduced. Therefore, in a process of generating an original image required for on-cell overlay measurement using the SEM device, a problem of excessive charge integrating in the chip region may be effectively prevented.

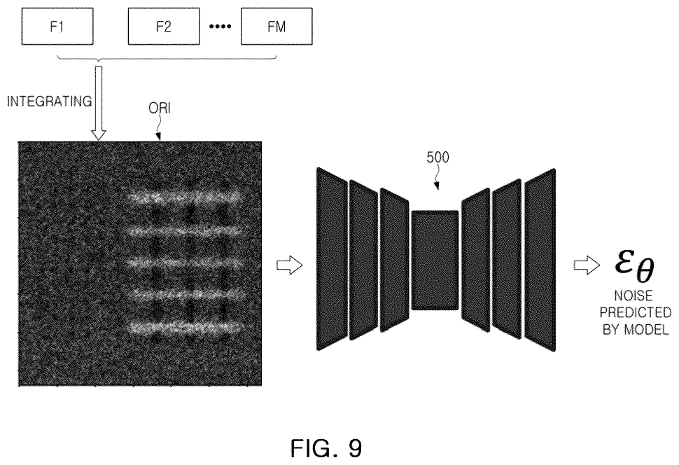

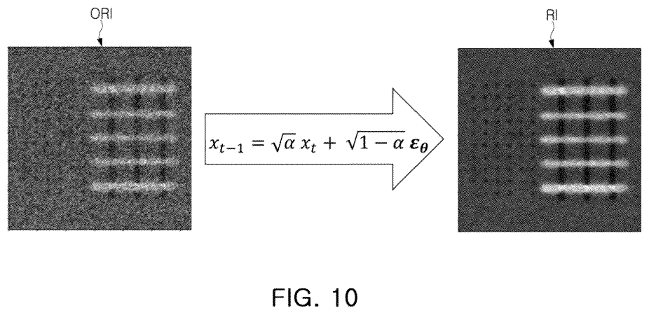

FIGS. 9 and 10 are diagrams illustrating a method for measuring an overlay according to an embodiment.

FIG. 9 is a diagram illustrating a method for measuring an overlay using a machine learning model 500 of which training is completed. Referring to FIG. 9, a single original image ORI may be generated by integrating a plurality of frames F1 to FM generated by a SEM device.

As described above, a task of integrating the plurality of frames F1 to FM may be executed by a server, a computer device, or the like, controlling the SEM device. For example, the SEM device may emit an electron beam to a target region multiple times with the same FOV to generate the M frames. The server controlling the SEM device may integrate the M frames F1 to FM, and may obtain, for example, an added average of the M frames, to acquire the single original image ORI.

Referring to FIGS. 6 and 9 together, quality of the original image ORI may be worse than the quality of the image 300 generated for training the machine learning model 500. This may be because the number of frames F1 to FN integrated in the image 300 generated for training is greater than the number of frames F1 to FM integrated in the original image ORI. In an embodiment, after training of the machine learning model 500 is completed, an overlay measurement task may be performed with the original image ORI integrated with a relatively small number of frames F1 to FM, thereby shortening a period of time required for the overlay measurement task and improving productivity.

The server in which the machine learning model 500 is stored may input the original image ORI into the machine learning model 500, and may perform an inference task to predict noise included in the original image ORI. When the original image ORI is input to the machine learning model 500, the machine learning model 500 may output predicted noise (ε_{θ}) estimating the original noise included in the original image ORI. The server may perform an image processing task to improve quality of the original image ORI by using the predicted noise (ε_{θ}) output by the machine learning model 500.

FIG. 10 is a diagram illustrating an example of an image processing task performed on a server. The server may acquire a result image RI with improved quality by performing an image processing task based on a formula such as Equation (1) for an original image ORI.

$${x}_{t - 1} = \sqrt{α} {x}_{t} + \sqrt{1 - α} {ε}_{θ} \qquad ( 1 )$$

In Equation (1), ε_{θ} may be predicted noise output by the machine learning model 500 inputting the original image ORI, a may be a difference between a variance value of the predicted noise (ε_{θ}) and 1, xₜ may be a value corresponding to the original image ORI, and xₜ₋₁ may be a value corresponding to the result image RI. The result image RI may have a similar quality to an image generated by integrating a larger number of frames than the number of frames F1 to FM integrated in the original image ORI. For example, the result image RI may have relatively higher clarity than the original image ORI. The server may perform an overlay measurement task using the result image RI that has improved quality, as compared to the original image ORI.

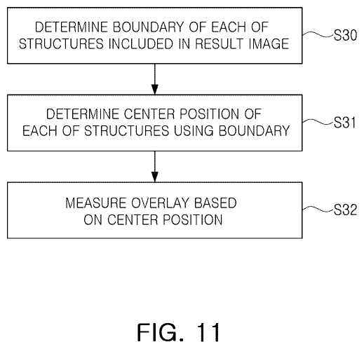

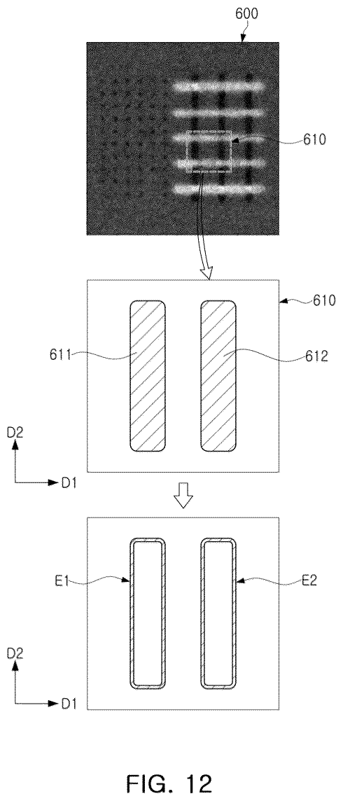

FIG. 11 is a flowchart illustrating a method for measuring an overlay according to an embodiment, and FIG. 12 is a diagram illustrating a method for manufacturing a semiconductor device according to an embodiment.

Referring to FIG. 11, a method for measuring an overlay according to an embodiment may start with determining a boundary of each structure included in a result image in operation S30. An overlay measurement method may be executed on a server predicting original noise included in an original image using a machine learning model and generating the result image with improved quality than the original image based thereon.

In operation S30, structures of which boundary is determined may be determined according to a target direction for which an overlay is to be determined by performing overlay measurement. Referring also to FIG. 12, a region-of-interest 610 may be determined in a result image 600, and structures 611 and 612 for determining the overlay may be selected in the region-of-interest 610. The server may determine a boundary E1 and E2 of each of the structures 611 and 612.

In operation S31, a center position of each structure may be determined using the boundary. In an embodiment, the boundary E1 and E2 of each of the structures 611 and 612 may be determined by distinguishing pixels corresponding to the structures 611 and 612 from pixels corresponding to a background therearound. For example, the boundary E1 and E2 may be determined with reference to brightness of each of the pixels. Once the boundary E1 and E2 may be determined, a center position of each of the structures 611 and 612 estimated to be located in the boundary E1 and E2 may be determined in at least one of a first direction D1 or a second direction D2. For example, the center position of each of the structures 611 and 612 may be determined in each of the first direction D1 and the second direction D2 by determining an average of coordinate values of the pixels located in the boundary E1 and E2.

Due to noise or the like, pixels separated by a certain distance from a position in which the structures 611 and 612 are expected to exist may show similar brightness to pixels located in the boundary E1 and E2. To reduce influence of noise, when a pixel significantly outside an expected coordinate range in which the structures 611 and 612 are expected to exist has a pixel value similar to pixels in the expected coordinate range, the pixel may not be adopted and be filtered out in a task of determining the boundary E1 and E2.

In addition, to reduce influence of noise, weights may be applied to pixel values of some of the pixels. For example, when the structures 611 and 612 are displayed brighter than the background therearound in the region-of-interest 610, brightness of pixels close to the boundary E1 and E2 of each of the structures 611 and 612 may be darker than brightness of pixels close to the center of each of the structures 611 and 612. In this case, weights may be applied to pixel values of each of the pixels according to brightness of the structures 611 and 612 and an average thereof may be determined, to reduce influence of noise and determine a center position of each of the structures 611 and 612 more accurately.

When the center position of each of the structures 611 and 612 is determined, the overlay may be measured based thereon in operation S32. The center position of each of the structures 611 and 612 may be determined by averaging or weighting coordinate values of the pixels located within the boundaries E1 and E2, and the center position of each of the structures 611 and 612 may be determined in each of the first direction D1 and the second direction D2. Therefore, an overlay in the first direction D1 and an overlay in the second direction D2 may be determined based on the center position of each of the structures 611 and 612.

The server may measure an overlay by comparing a center position of each of the structures 611 and 612 with a center position of each of the other structures disposed at a different height from the structures 611 and 612. For example, the structures 611 and 612 may be disposed on a first level defined at a first height, and other structures that at least partially overlap the structures 611 and 612 may be disposed at a second level, defined at a second height different from the first height. The server may measure the overlay by comparing a center position of each of the structures 611 and 612 on the first level with a center position of each of the structures disposed on the second level.

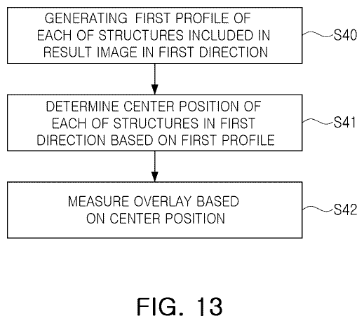

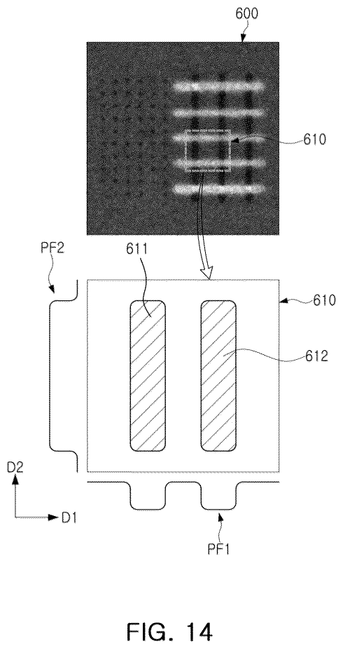

FIG. 13 is a flowchart illustrating a method for measuring an overlay according to an embodiment. FIGS. 14 to 17 are diagrams illustrating a method for measuring an overlay according to an embodiment.

Referring to FIG. 13, a method for measuring an overlay according to an embodiment may start with generating a first profile of structures included in a result image in the first direction in operation S40. The method for measuring an overlay may be executed on a server predicting original noise included in an original image using a machine learning model and generating the result image with improved quality compared to the original image based thereon.

The first profile determined in operation S40 may be generated by determining an average of pixel values of pixels disposed at the same position in the first direction in which an overlay is to be measured. The first profile may appear differently depending on the number and shapes of structures included in the result image. When the first profile is generated, the server may determine a center position of each of the structures in the first direction using the first profile in operation S41. The server may measure the overlay in the first direction using the center position of each of the structures determined based on the first profile in operation S42.

For example, the server may compare the center position of each of the structures determined based on the first profile with a center position of each of other structures, to measure an overlay. For example, the structures used to generate the first profile may be disposed on a first level, and other structures may be disposed on a second level, different from the first level. The other structures may have a region overlapping the structures used to generate the first profile. The server may compare a center position of each of the structures determined based on the first profile with a center position of each of the structures disposed on the second level, to measure an overlay.

Hereinafter, a method for measuring an overlay using a profile will be described in more detail with reference to FIGS. 14 to 17.

First, referring to FIG. 14, a region-of-interest 610 may be selected from a result image 600. A server performing the overlay measurement may acquire the result image 600 using an original image generated by a SEM device. For example, a server may input an original image into a trained machine learning model to acquire predicted noise estimating original noise included in an original image, and may process the original image using the predicted noise to acquire the result image 600 with improved quality compared to the original image.

When a region-of-interest 610 is selected, the server may generate profiles PF1 and PF2 of structures 611 and 612 disposed in the region-of-interest 610. Referring to FIG. 14, a first profile PF1 may be generated in the first direction D1, and a second profile PF2 may be generated in the second direction D2 intersecting the first direction D1. The profiles PF1 and PF2 may be selectively generated depending on a direction in which an overlay is to be determined. For example, when determining an overlay in the first direction D1, the first profile PF1 may be generated, and when determining an overlay in the second direction D2, the second profile PF2 may be generated.

The profiles PF1 and PF2 may be generated by adding or averaging pixel values of pixels disposed at the same position in a direction corresponding to a profile corresponding thereto. For example, the first profile PF1 may be generated by determining an average of pixel values from pixels disposed at the same position in the first direction D1 and disposed in the second direction D2. The second profile PF2 may be generated by determining an average of pixel values from pixels disposed at the same position in the second direction D2 and disposed in the first direction D1.

The server may determine a center position of each of the structures 611 and 612 in the first direction D1 using the first profile PF1, and may measure an overlay in the first direction D1 based on the center position. The server may use the second profile PF2 to determine a center position of the structures 611 and 612 in the second direction D2, and may measure an overlay in the second direction D2 based on the center position. The overlay measured by the server from the structures 611 and 612 may be an on-cell overlay measured in the chip region of the wafer, and for example, the server may execute an MRC task for correcting an error of an overlay measured from an overlay key pattern of a scribing region with reference to the on-cell overlay measured from the structures 611 and 612.

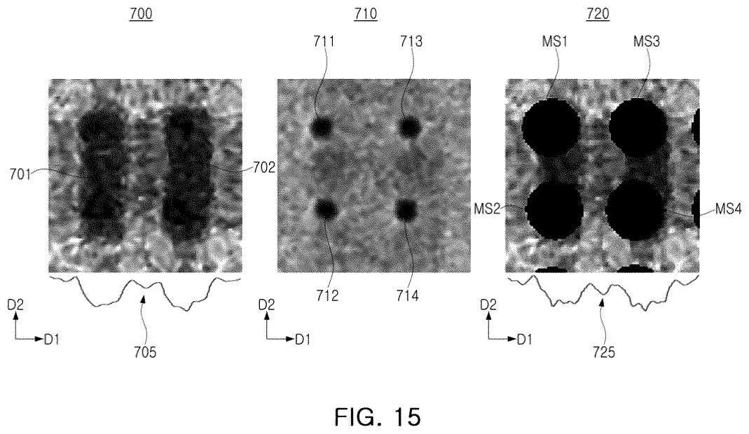

Referring to FIG. 15, a raw profile 705 of structures 701 and 702 included in a first result image 700 may be generated. The raw profile 705 may be a profile generated to measure an overlay in the first direction D1. For example, the first profile 705 may be generated by averaging pixel values of pixels disposed in the second direction D2 and located at the same position in the first direction D1.

The first result image 700 may be an image generated by a SEM device, and the first result image 700 may be generated from signals due to secondary electrons and signals due to back-scattered electrons. For example, when structures 701 and 702 required for overlay measurement are located on a level emitting the back-scattered electrons, a filtering operation for reducing influence due to the secondary electrons may be performed first.

In an embodiment, a second result image 710 generated by the secondary electrons may be filtered from the first result image 700. For example, noise patterns 711 to 714 appearing in the second result image 710 by structures located on a level emitting the secondary electrons may be masked in the first result image 700. Referring to FIG. 15, masking regions MS1 to MS4 filtered in the first result image 700 may be determined by the noise patterns 711 to 714 included in the second result image 710.

A first profile 725 generated from structures included in a filter image 720 on which masking processing is completed may be a profile for measuring an overlay in the first direction D1 and different from the raw profile 705 generated from the first result image 700 before the masking processing. In this manner, in an embodiment, based on a level on which the structures 701 and 702, which may be measurement targets of an overlay, are located, a noise pattern due to electrons emitted on a different level from the structures 701 and 702 may be masked. Therefore, influence of noise may be effectively reduced, and accuracy of the overlay measurement may be improved.

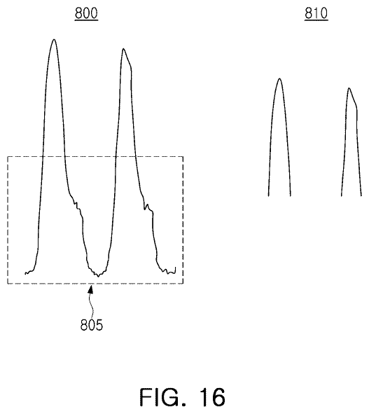

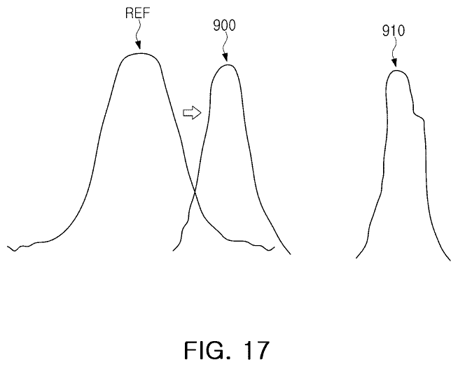

The first profile 725 for measuring an overlay in the first direction D1 may be generated by adding or averaging pixel values of pixels disposed at the same position in the first direction D1 and disposed in the second direction D2. In an embodiment, a reference profile may be generated using the first profile 725, and a center position of each of the structures 701 and 702 corresponding to the first profile 725 may be determined by determining correlation between the first profile 725 and the reference profile. This will be described in more detail below with reference to FIGS. 16 and 17.

First, referring to FIG. 16, a first profile 800 may be generated from a region-of-interest, which may be a result image or a portion of the result image. The first profile 800 may be generated for measuring an overlay in one direction, and the first profile 800 may be generated differently depending on the number, shapes, or the like of structures included in the result image. In an embodiment illustrated in FIG. 16, it may be estimated that two structures are present in the result image used to generate the first profile 800 or a region-of-interest of the result image.

As illustrated in FIG. 16, when the first profile 800 is generated, a reference profile may be generated using the first profile 800. In an embodiment, after filtering out an asymmetric region 805 in the first profile 800, the reference profile may be determined as an average of two unit profiles corresponding to two structures included in the first profile 800.

When the reference profile is generated, a center position of a structure corresponding to each of the unit profiles may be determined by determining correlation between the reference profile and each of the unit profiles. Referring to FIG. 17, a position with highest correlation with a reference profile REF may be found by sliding and intersecting the reference profile REF with each of unit profiles 900 and 910. A first unit profile 900 and a second unit profile 910 may be profiles generated from one result image.

In the first unit profile 900, a position with highest correlation with the reference profile REF may be found to determine a center position of a first structure corresponding to the first unit profile 900. Similarly, in the second unit profile 910, a position with highest correlation with the reference profile REF may be found to determine a center position of a second structure corresponding to the second unit profile 910. In this manner, in an embodiment, a profile according to a direction in which an overlay is to be measured in a result image may be generated, a reference profile may be generated from the profile, and correlation between the reference profile and each profile may be determined, thereby determining a center position of each of structures included in the result image. Based on the center position of each of the structures determined as described above, an overlay may be accurately measured.

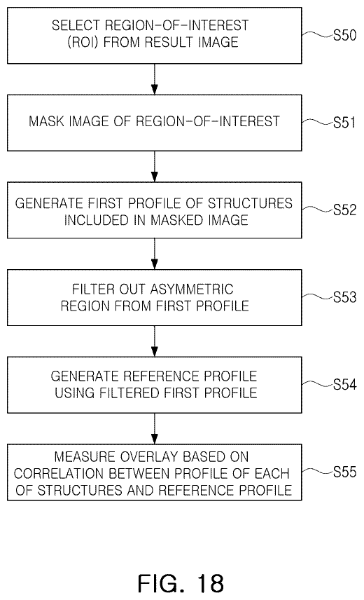

FIG. 18 is a flowchart illustrating a method for measuring an overlay according to an embodiment.

Referring to FIG. 18, a method for measuring an overlay by a SEM device according to an embodiment may start with selecting a region-of-interest from a result image in operation S50. The result image of operation S50 may be an image acquired by inputting an original image generated by the SEM device into a machine learning model.

The original image generated by the SEM device may be transmitted to a server controlling the SEM device. The server may execute an inference task using a pre-trained machine learning model, and as an example, the machine learning model may be a generative model trained to predict noise included in the original image as in the embodiments described above. Since quality of the original image may be improved by using the machine learning model, the SEM device may integrate only a small number of frames to generate the original image. As an example, the number of frames integrated to generate the original image may be less than 10.

The server may input the original image into the machine learning model to predict noise in the original image, and may process the original image using this to acquire a result image with improved quality. When a region-of-interest for measuring an overlay is selected from the result image, the server may mask an image of the region-of-interest in operation S51.

The original image generated by the SEM device may be an image composed of signals generated by back-scattered electrons, secondary electrons, or the like. For example, when structures to be used for overlay measurement in a region-of-interest are located on a level emitting the back-scattered electrons (BSE), the server may mask a scattered electron (SE) image from a BSE image. When structures to be used for overlay measurement in a region-of-interest are located on a level emitting the secondary electrons, the server may mask the BSE image from the SE image.

After a masking process is completed, the server may generate a first profile of structures included in the masked image in operation S52. The first profile may be generated by summing or averaging pixel values of pixels or the like. For example, when measuring an overlay in the first direction, the first profile may be generated by summing or averaging pixel values of pixels disposed at the same position in the first direction and disposed in the second direction.

After the first profile is generated, the server may filter out an asymmetric region from the first profile in operation S53. For example, as described above with reference to FIG. 17, the asymmetric region may be filtered out from the first profile. The asymmetric region filtered out in operation S53 may be a region generated from other structures existing on a different level from a level on which structures for which the overlay is to be measured are formed. The server may generate a reference profile using the first profile from which the asymmetric region is filtered out in operation S54.

After the reference profile is generated, an overlay may be measured based on correlation between the profile of each of the structures and the reference profile in operation S55. For example, the server may determine a center position of each of the structures by finding a position with highest correlation with the reference profile in each of the structures, and may measure the overlay based thereon.

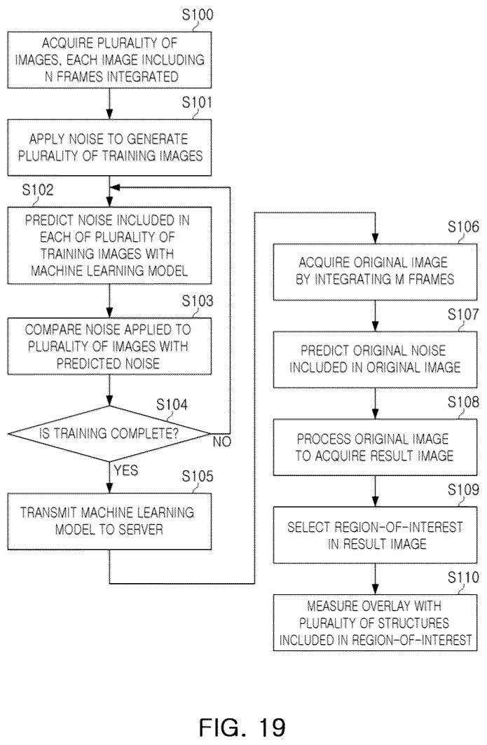

FIG. 19 is a flowchart illustrating a method for measuring an overlay according to an embodiment.

Referring to FIG. 19, a method for measuring an overlay by a SEM device according to an embodiment may start with acquiring an image as a plurality of images in which N frames are integrated in operation S100. Each of the N frames may be an image generated by the SEM device by emitting an electron beam to a target region of an object and using the electron beam reflected from the target region, and N may be a natural number equal to or greater than 2. For example, the SEM device may integrate dozens of frames to generate an image with high quality.

The plurality of images acquired by the SEM device may be transmitted to a training server training a machine learning model. The training server may apply noise to each of the plurality of images to generate a plurality of training images in operation S101. The noise applied to each of the plurality of images in operation S101 may be Gaussian noise, and the training server may apply different noises to one image to generate two or more training images from the one image.

The training server may input each of the plurality of training images into the machine learning model, and the machine learning model may predict noise included in each of the plurality of training images in operation S102. The training server may compare predicted noise predicted by the machine learning model in operation S102 with noise included in the training image in operation S103. The training server may compare the noise included in the training image with the predicted noise using a predetermined loss function, and may determine whether training is complete in operation S104.

When the training is complete, the training server may transmit the machine learning model to the server in operation S105. The server receiving the machine learning model in operation S105 may be a server controlling a SEM device, a semiconductor process facility performing a semiconductor process, and the like. According to an embodiment, the training server may be implemented as a single integrated server with the server.

Thereafter, a task of measuring an overlay while performing the semiconductor process may be performed. The task of measuring an overlay according to an embodiment may include a task of measuring an overlay using an overlay key pattern formed in a scribing region, a task of measuring an on-cell overlay using an image of structures formed in a chip region captured by the SEM device, or the like.

For overlay measurement, the SEM device may capture a target region in a chip region such as a wafer or the like. The server may acquire an original image acquired by integrating M frames captured by the SEM device in the target region in operation S106. For example, a task of integrating the M frames may be executed by the SEM device or may be executed by the server.

The server may input the original image into the machine learning model received and stored in operation S105, to estimate original noise included in the original image in operation S107. For example, the machine learning model may output a predicted average value and a predicted standard deviation value, predicting the original noise included in the original image. In an embodiment, the noise included in the original image captured by the SEM device may have a distribution close to a Gaussian distribution as the original image is generated by integrating M frames. Therefore, based on the predicted average value and the predicted standard deviation value, output by the machine learning model, the original noise included in the original image may be predicted.

The server may process the original image with reference to predicted noise determined by the machine learning model, to acquire a result image having improved quality compared to the original image in operation S108. For example, the result image generated in operation S108 may have similar quality to an image generated by integrating a number of frames greater than M, which may be the number of frames integrated in the original image.

The server may select a region-of-interest for measuring an overlay in the result image in operation S109. The region-of-interest may include a plurality of structures, and the server may measure an overlay with the plurality of structures included in the region-of-interest in operation S110.

In an embodiment, the overlay measurement method of operation S110 may be executed by the segmentation method described with reference to FIGS. 12 and 13 above and/or the projection method described with reference to FIGS. 14 to 18. For example, a boundary of each of the plurality of structures included in the region-of-interest may be determined, and a center position of each of the plurality of structures may be determined based thereon, thereby measuring the overlay. Alternatively, profiles represented by the plurality of structures may be generated, and the center positions of each of the plurality of structures may be determined from the profiles, thereby measuring the overlay. The server may control the semiconductor process facility performing the semiconductor process based on the overlay measurement results.

According to an embodiment, a low-quality image captured at high speed by a SEM device may be converted into a high-quality image using a machine learning model trained to predict noise included in the low-quality image. Therefore, productivity of an overlay measurement work may increase by shortening a period of time required for the SEM device to capture an image to determine an overlay in a semiconductor chip, and yield of a semiconductor process may be improved by accurately determining an overlay using an image captured an internal space of the semiconductor chip.

A semiconductor process system according to an embodiment includes a SEM device generating one original image in which two or more frames by which a target region of a wafer is captured are integrated, a server storing a machine learning model trained to predict noise included in the original image, and a semiconductor process facility performing a semiconductor process on the wafer, where the server processes the original image with reference to the noise predicted by the machine learning model to generate a result image, measures an overlay of the wafer using the result image, and controls the semiconductor process facility based on a measurement result of the overlay.

A semiconductor process system according to an embodiment further includes a training server training the machine learning model, where the training server applies noise to an image generated by the SEM device to generate a plurality of training images, inputs the plurality of training images to the machine learning model to acquire an predicted noise output by the machine learning model, and compares the predicted noise with the noise of each of the plurality of training images to train the machine learning model.

In a semiconductor process system according to an embodiment, the number of frames integrated in the original image may be less than the number of frames integrated in the image generated by the SEM device for training the machine learning model.

In a semiconductor process system according to an embodiment, the server may generate a first profile represented by structures included in the result image in a first direction, determine a center position of each of the structures in the first direction based on the first profile, and measure an overlay in the first direction based on the center position.

In a semiconductor process system according to an embodiment, the server may determine a boundary of each of structures included in the result image, determine a center position of each of the structures based on the boundary, and measure an overlay based on the center position.

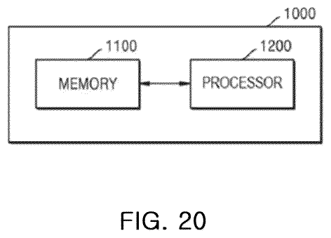

FIG. 20 is a block diagram of a system according to one or more embodiments.

As shown in FIG. 20, the system 1000 may include a memory 1100 and a processor 1200. However, the configuration shown in FIG. 20 is an example for implementing the embodiments, and other hardware and software configurations may be additionally included in the system 1000 as will be understood to one of ordinary skill in the art from the disclosure herein. According to one or more embodiments, the system 1000 may be implemented in the form of an electronic device.

The system 1000 according to one or more embodiments may be configured to perform operations according to the embodiments disclosed herein.

The memory 1100 may store commands or data related to at least one other component of the system 1000. Also, the memory 1100 may be accessed by the processor 1200, and reading/writing/modifying/deleting/updating of data may be performed by the processor 1200.

The term memory may include the memory 1100, a read-only memory (ROM) or a random access memory (RAM) in the processor 1200, or a memory card (e.g., a micro secure digital (SD) card or a memory stick) mounted in the system 1000. In addition, the memory 1100 may store programs and data for configuring various screens to be displayed on a display area of a display.

According to one or more embodiments, the memory 1100 may include a non-volatile memory capable of maintaining stored information even if power supply is interrupted, and a volatile memory requiring continuous power supply to maintain stored information. For example, the non-volatile memory may be implemented as at least one of one time programmable ROM (OTPROM), programmable ROM (PROM), erasable and programmable ROM (EPROM), electrically erasable and programmable ROM (EEPROM), mask ROM, or flash ROM, and the volatile memory may be implemented as at least one of dynamic RAM (DRAM), static RAM (SRAM), or synchronous dynamic RAM (SDRAM).

The processor 1200 may be electrically connected to the memory 1100 to control all operations and functions of the system 1000.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software including one or more instructions that are stored in a storage medium that is readable by a machine. For example, a processor of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

At least one of the devices, units, components, modules, units, or the like represented by a block or an equivalent indication in the above embodiments may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A method of measuring an overlay, comprising:
obtaining a plurality of first images, each of the plurality of first images being generated by integrating N first frames generated by a scanning electron microscope (SEM) device, wherein Nis a natural number equal to or greater than 2;
generating a plurality of training images by respectively applying noise to the plurality of first images;
inputting the plurality of training images into a machine learning model;
obtaining, from the machine learning model, predicted noise by determining, by the machine learning model, noise in each of the plurality of training images;
training the machine learning model by respectively comparing the predicted noise of the plurality of training images with the noise applied to the plurality of first images;
obtaining an original image in which M second frames generated by the SEM device are integrated, wherein M is a natural number less than N;
obtaining a result image by inputting the original image into the machine learning model for which training is completed; and
measuring an overlay based on the result image.

2. The method of claim 1, wherein Nis at least twice M.

3. The method of claim 1, further comprising:
determining a boundary of at least one structure in the result image; and
determining a center position of the at least one structure based on the boundary; and
wherein measuring the overlay comprises measuring the overlay based on the center position.

4. The method of claim 3, wherein determining the center position of the at least one structure comprises:
determining a first center position of the at least one structure from a first result image corresponding to a first level at a first height; and
determining a second center position of the at least one structure from a second result image corresponding to a second level at a second height that is different from the first height, and
wherein measuring the overlay based on the center position comprises comparing the first center position and the second center position.

5. The method of claim 1, further comprising:
obtaining a first profile represented by at least one structure in the result image in a first direction; and
determining at least one first center position of the at least one structure in the first direction based on the first profile, and
wherein measuring the overlay comprises measuring the overlay in the first direction based on the at least one first center position.

6. The method of claim 5, further comprising:
obtaining a first result image of a predetermined target region captured at a first height, and a second result image of the predetermined target region captured at a second height that is different from the first height;
acquiring a filter image by filtering the second result image from the first result image; and
generating the first profile represented by the at least one structure in the filter image in the first direction.

7. The method of claim 5, further comprising:
obtaining a second profile represented by the at least one structure in the result image in a second direction that is perpendicular to the first direction; and
determining at least one second center position of the at least one structure in the second direction based on the second profile, and
wherein measuring the overlay comprises measuring the overlay in the second direction based on the at least one second center position.

8. The method of claim 5, further comprising:
acquiring a filtered profile by deleting an asymmetric region corresponding to at least a portion of the first profile,
wherein determining the at least one first center position comprises determining the at least one first center position of the at least one structure in the first direction based on the filtered profile, and
wherein measuring the overlay comprises measuring the overlay in the first direction based on the at least one first center position.

9. The method of claim 8, further comprising:
generating a reference profile based on the filtered profile; and
determining the at least one first center position by generating a correlation coefficient between the reference profile and the filtered profile.

10. The method of claim 1, further comprising:
determining original image predicted noise that estimates original noise in the original image by inputting the original image into the machine learning model, and
wherein obtaining the result image comprises processing the original image based on the original image predicted noise.

11. The method of claim 10, wherein the original image predicted noise comprises a predicted average value and a predicted standard deviation value that estimate the original noise.

12. The method of claim 1, wherein the result image comprises an image in which the SEM device captures a target region in at least one chip region among a plurality of chip regions, and
wherein the method further comprises compensating an error of an overlay measured from an overlay key pattern formed in a scribing region between the plurality of chip regions based on the overlay measured based on the result image.

13. A method of measuring an overlay, comprising:
inputting a training image into a machine learning model, the training image comprising an image captured by a scanning electron microscope (SEM) device to which noise is applied;
determining a loss function based on a predicted average value and a predicted standard deviation value that are output by the machine learning model, and an actual average value and an actual standard deviation value in the noise applied to the training image;
training the machine learning model; and
based on the training being completed, storing the machine learning model in a server, the machine learning model being configured to control the SEM device.

14. The method of claim 13, wherein the training the machine learning model is executed in a training server that is separate from the server.

15. The method of claim 13, wherein the machine learning model comprises a generative model.

16. A method of measuring an overlay, comprising:
obtaining an original image in which M frames generated by a scanning electron microscope (SEM) device are integrated, wherein M is a natural number equal to or greater than 2;
obtaining a predicted average value and a predicted standard deviation value that estimate noise in the original image by inputting the original image into a machine learning model;
generating a result image by processing the original image using the predicted average value and the predicted standard deviation value;
determining a center position of each of structures in the original image based on the result image; and
measuring an overlay based on the center position of each of the structures.

17. The method of claim 16, wherein integrating is 2 or more and less than 10.

18. The method of claim 16, wherein the machine learning model is configured to predict the noise in the original image as a Gaussian distribution.

19. The method of claim 16, wherein the SEM device is configured to generate the M frame by capturing at least one target region in a plurality of chip regions in a wafer.

20. The method of claim 19, wherein measuring the overlay comprises:
measuring a first overlay based on an overlay key pattern in a scribing region between the plurality of chip regions on the wafer; measuring a second overlay based on the center position of each of the structures; and
compensating for an error of the first overlay based on the second overlay.
